(19) United States
(12) Patent Application Publication
(10) Pub. No.: US 2016/0099408 A1
(43) Pub. Date: Apr. 7, 2016

(54) MANUFACTURING METHOD FOR INSULATING FILM AND MANUFACTURING APPARATUS FOR THE SAME

(71) Applicants: Makoto NAGAMINE, Seoul (KR); Youngmin EEH, Seoul (KR); Koji UEDA, Seoul (KR); Daisuke WATANABE, Seoul (KR); Kazuya SAWADA, Seoul (KR); Toshihiko NAGASE, Seoul (KR)

(72) Inventors: Makoto NAGAMINE, Seoul (KR); Youngmin EEH, Seoul (KR); Koji UEDA, Seoul (KR); Daisuke WATANABE, Seoul (KR); Kazuya SAWADA, Seoul (KR); Toshihiko NAGASE, Seoul (KR)

(21) Appl. No.: 14/639,651

(22) Filed: Mar. 5, 2015

Related U.S. Application Data
(60) Provisional application No. 62/059,071, filed on Oct. 2, 2014.

(51) Int. Cl. H01L 43/12; C23C 14/08; G01B 15/02; C23C 14/52; C23C 14/54; H01L 27/22; C23C 14/34

(52) U.S. Cl. CPC H01L 43/12; H01L 27/226; C23C 14/081; C23C 14/3414; C23C 14/52; C23C 14/34; C23C 14/545; G01B 15/02

(57) ABSTRACT

According to one embodiment, a method of manufacturing an insulating film, includes forming an insulating film on a substrate by sputtering, measuring a thickness of the insulating film at a plurality of locations, and irradiating a surface portion of the insulating film with X rays or ions, based on the measured thickness.

### CROSS-REFERENCE TO RELATED APPLICATIONS

This application claims the benefit of U.S. Provisional Application No. 62/059,071, filed Oct. 2, 2014, the entire contents of which are incorporated herein by reference.

### FIELD

Embodiments described herein relate generally to a method for manufacturing an insulating film, an insulating film manufacturing apparatus, and a method for manufacturing a magnetoresistive element.

### BACKGROUND

Recently, a large-capacity magnetoresistive random access memory (MRAM) using a magnetic tunnel junction (MTJ) element has been expected and has attracted attention. In the MTJ element used in the MRAM, one of two ferromagnetic layers sandwiching a tunnel barrier layer is handled as a magnetization-fixed layer (reference layer) which has a magnetizing direction fixed not to be easily varied, and the other is handled as a magnetization free layer (memory layer) which allows a magnetizing direction to be invertible. By associating a parallel state and an antiparallel state of the magnetizing directions of the reference layer and the memory layer with binary numbers “0” and “1”, information can be stored.

### BRIEF DESCRIPTION OF THE DRAWINGS

FIG. 1 is a cross-sectional view showing a structure of an MTJ element.

FIG. 2 is a graph showing a relationship between a wafer position and a thickness of an MgO film.

FIG. 3 is a graph showing a relationship between a wafer position and a resistance of an MgO film.

FIGS. 4A to 4C are cross-sectional views showing steps of manufacturing an insulating film of a first embodiment.

FIGS. 5A and 5B are cross-sectional views showing another example of the steps of manufacturing the insulating film of the first embodiment.

FIG. 6 is a block diagram schematically showing an apparatus for manufacturing an insulating film of a second embodiment.

FIG. 7 is a schematic illustration showing an example of a sputtering mechanism utilized in the manufacturing apparatus shown in FIG. 6.

FIG. 8 is a schematic illustration showing an example of a film thickness distribution measuring mechanism utilized in the manufacturing apparatus shown in FIG. 6.

FIG. 9 is a schematic illustration showing an example of an ion irradiation mechanism utilized in the manufacturing apparatus shown in FIG. 6.

FIG. 10 is a schematic illustration showing another example of the apparatus for manufacturing the insulating film.

FIG. 11 is a circuit configuration diagram showing an MRAM of a third embodiment.

FIG. 12 is a cross-sectional view showing a structure of a memory cell module used for the MRAM shown in FIG. 11.

FIGS. 13A to 13F are cross-sectional views showing steps of manufacturing the memory cell module shown in FIG. 12.

### DETAILED DESCRIPTION

In general, according to one embodiment, a method of manufacturing an insulating film, comprises forming an insulating film on a substrate by sputtering, measuring a thickness of the insulating film at a plurality of locations, and irradiating a surface portion of the insulating film with X rays or ions, based on the measured thickness.

Embodiments will be described hereinafter with reference to the accompanying drawings.

### First Embodiment

An MTJ element used for an MRAM is formed by sandwiching a nonmagnetic layer (tunnel barrier layer) 2 of MgO, etc. between a first ferromagnetic layer 1 and a second ferromagnetic layer 3 of CoFeB, etc. as shown in FIG. 1. To improve a property of the MTJ element, resistance distribution of the nonmagnetic layer 2 having a greater resistance than that of the ferromagnetic layers 1 and 3 needs to be uniformed.

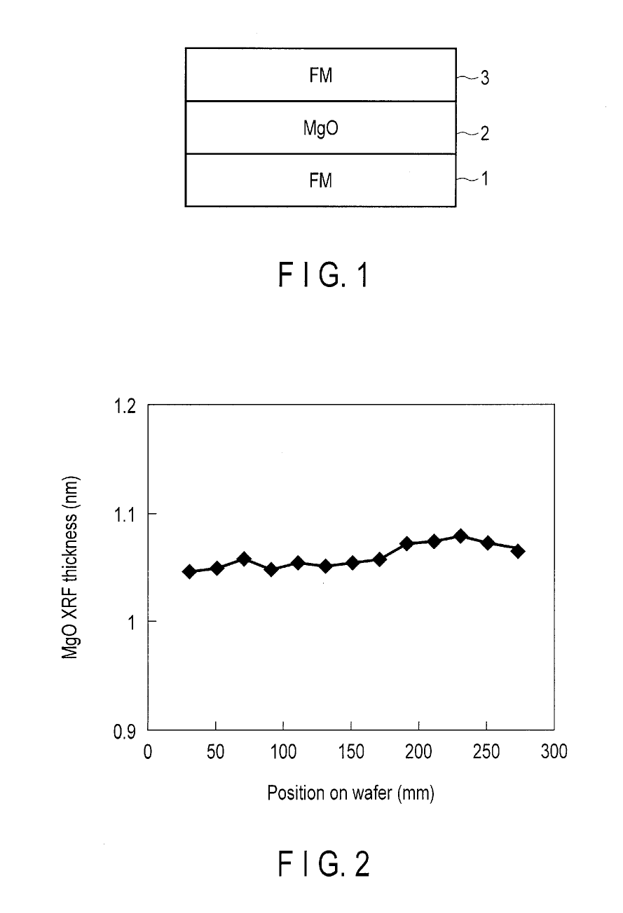

FIG. 2 is a graph showing a distribution of a thickness of an MgO film serving as the nonmagnetic layer 2. A horizontal axis indicates a wafer position, and a center in a horizontal direction of the wafer is positioned in 150 nm. A vertical axis indicates a thickness of the MgO film measured by X-ray Fluorescence Analysis (XRF) for detecting fluorescent X rays generated by X-ray irradiation. The MgO film is formed by sputtering, but is not necessarily formed to have a uniform thickness.

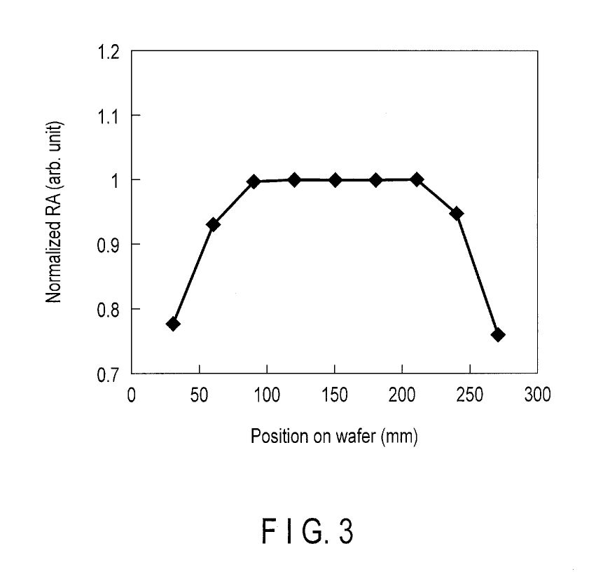

FIG. 3 is a graph showing a resistance distribution of an MgO film, i.e., a resistance of the MgO film in a thickness direction plotted at a position on a wafer in an in-plane direction. Originally, the resistance value in the film thickness direction should be proportional to the film thickness, but the resistance becomes sharply smaller at peripheral portions as understood from FIG. 3. This is because defects, etc. resulting from a process of forming the MgO film may occur at the peripheral portions of the wafer and cause the resistance to be smaller. This problem can be solved by optimally setting the film forming conditions to prevent occurrence of the defects, but a difference in resistance based on a difference in film thickness cannot be eliminated.

Thus, the present embodiment is characterized by forming the MgO film under the film forming conditions that would not cause the defects and correcting the difference in resistance based on the difference in film thickness by generating a defect by irradiation of X rays or ions.

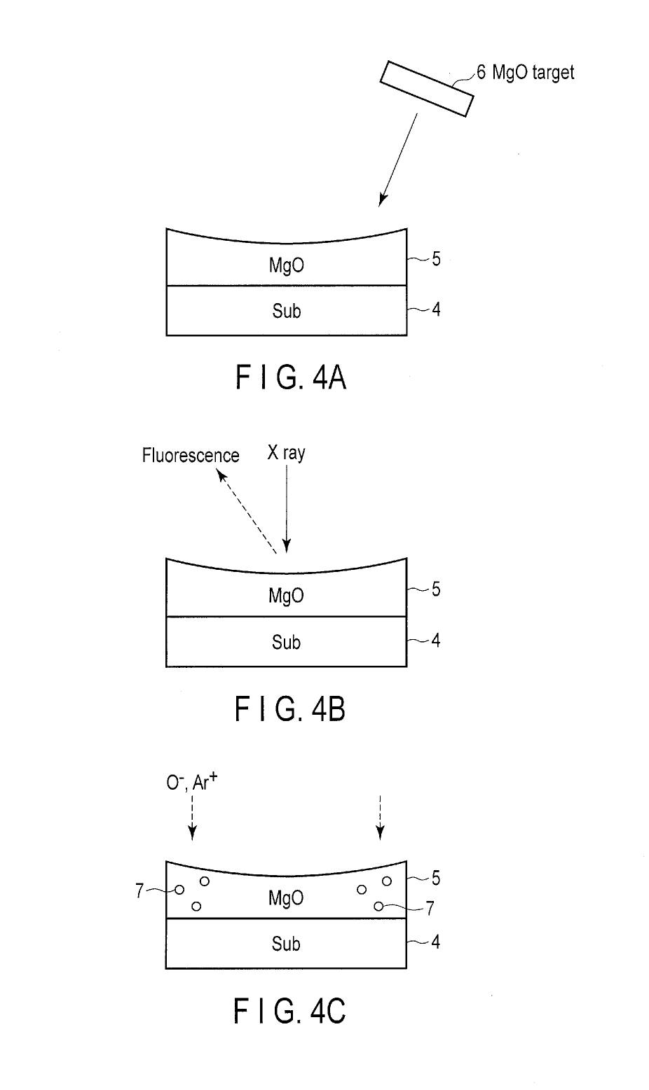

FIGS. 4A to 4C are cross-sectional views showing steps of manufacturing an insulating film of the first embodiment. As the insulating film, MgO that is employed as a tunnel barrier layer of the MTJ element is used.

First, an MgO film 5 is deposited on a substrate 4 by sputtering an MgO target 6 as shown in FIG. 4A. At this time, conditions that would not cause a defect as much as possible are set as the film forming conditions. The substrate 4 is to be a base, and is a magnetic layer if the MTJ element is formed.

Then, as shown in FIG. 4B, a surface of the MgO film 5 is irradiated with X rays, fluorescent X rays generated on the surface of the MgO film 5 are detected, and a thickness of the MgO film 5 is thereby measured. In other words, the thickness distribution of the MgO film 5 is measured by the XRF of detecting characteristic X rays (fluorescent X rays) emitted when inner shell electrons are ejected by irradiation of the X rays and other electrons enter an empty electron orbit. In this embodiment, the film thickness is great at the peripheral portions of the wafer.

Next, the surface portion of the MgO film 5 is selectively irradiated with high-energy ions (for example, Ar and O ions), based on the measured film thickness distribution, as shown in FIG. 4C. A defect occurs at a portion irradiated with the ions, and a resistance becomes small at this portion. By recognizing a portion of a smallest thickness as a criterion and irradiating a portion of a greater thickness than this with ions, the resistance distribution can be uniformed. Furthermore, the resistance distribution can also be further uniformed by varying the ion irradiation amount in accordance with an excessive amount of the film thickness.

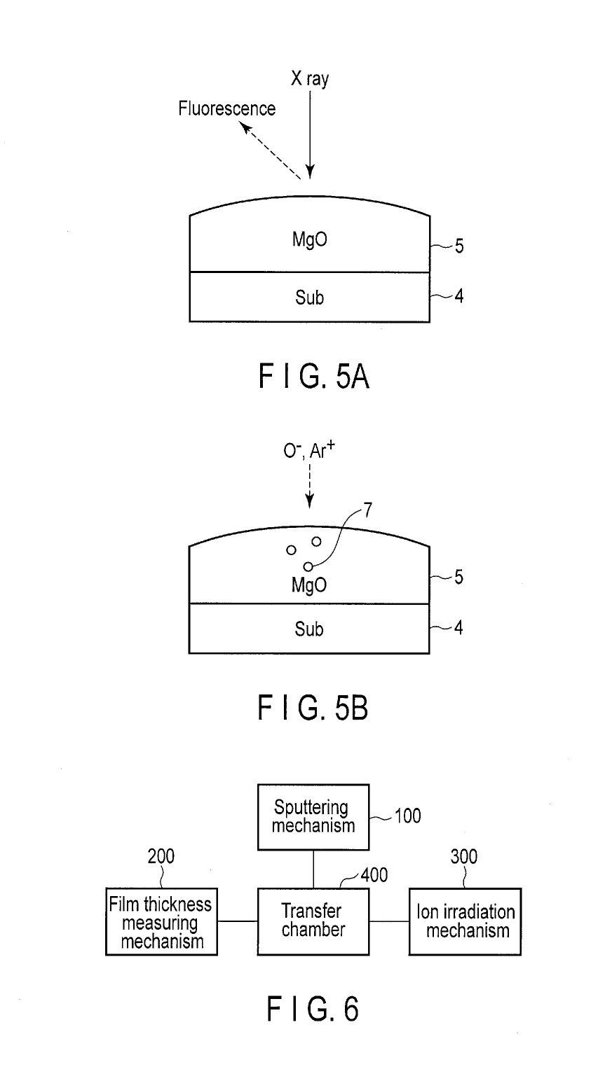

In addition, if the film thickness of the MgO film 5 is greater at the central portion as shown in FIG. 5A, the central portion of the MgO film 5 needs only to be irradiated with the ions as shown in FIG. 5B.

The type of the ions for irradiation of the MgO film 5 is not limited to Ar or O, but As, B, BF₂, C, F, Ge, In, N, P, Si, Mg, etc. can also be used as the ions. A defect in the insulating film is also generated by not only irradiation of the ions, but also irradiation of the X rays. Accordingly, the resistance distribution of the MgO film 5 can also be uniformed by irradiation of the X rays instead of the ions.

Thus, according to the present embodiment, the difference in resistance based on the difference in the film thickness of the MgO film 5 can be corrected by measuring the film thickness of the MgO film 5 formed by the sputtering, by the XRF, and irradiating the MgO film 5 with the X rays or ions in accordance with the measured film thickness. For this reason, the resistance distribution uniform in the radial direction can be obtained. This is effective when the MgO film is used as a tunnel barrier layer of the MTJ element.

In the sputtering, both the condition for no defect and the condition for the uniform film thickness can hardly be met, but any one of the conditions can be met comparatively easily. In the present embodiment, a portion having a difference in film thickness can be corrected in an after-treatment if the process condition for no defect is met. Therefore, the present embodiment also has an advantage of increasing the process margin at the film formation.

### Second Embodiment

FIG. 6 is a schematic block diagram showing an insulating film manufacturing apparatus of a second embodiment.

To form the MgO film of the first embodiment, a sputtering mechanism 100, a film thickness distribution measuring mechanism 200, and an ion irradiation mechanism 300 are required. The mechanisms 100, 200, and 300 are connected to each other via a transfer chamber 400.

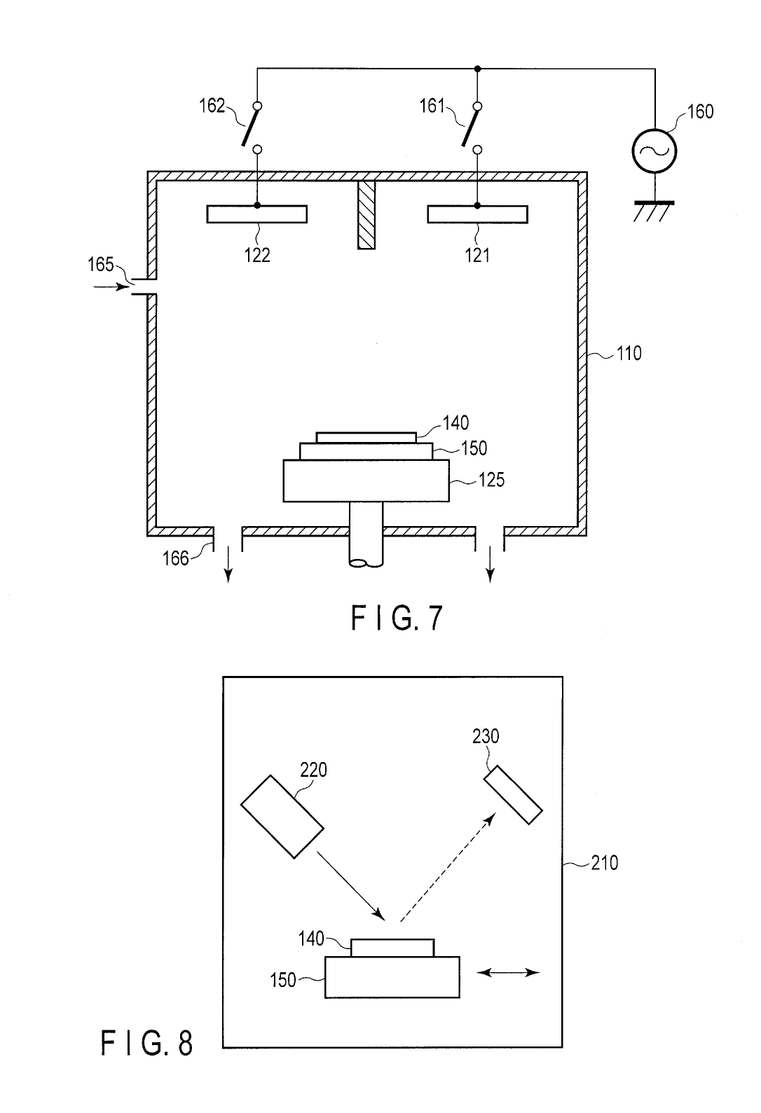

The sputtering mechanism 100 is constituted by arranging an MgO target (nonmagnetic target) 121 and a CoFeB target (magnetic target) 122 serving as sputtering sources, at an upper portion in a chamber 110, as shown in FIG. 7. By sputtering the MgO target 121 in an Ar gas atmosphere, the MgO film can be formed on the substrate 140. In addition, by sputtering the CoFeB target 122 in the Ar gas atmosphere, a CoFeB film can be deposited on the substrate 140.

A rotary stage 125 which can be rotated by a motor, etc. (not shown) is provided under an interior of the chamber 110. A substrate stage 150 on which a substrate 140 is placed can be placed on the rotary stage 125.

The target 121 is connected to an RF power supply 160 via a switch 161, and the target 122 is connected to the RF power supply 160 via a switch 162. An RF power can be selectively applied to the target 121 or 122 by selection of the switches 161 and 162.

In addition, a gas inlet 165 through which an inert gas such as Ar, etc. is introduced is provided at the chamber 110. Furthermore, an outlet 166 through which the gas in the chamber 110 is discharged is provided at the chamber 110.

A shutter, which is not shown in the figure, may be provided before (below) the targets 121 and 122. Furthermore, a sub-shutter may be provided above the rotary stage to temporarily cover surfaces of the substrate 140 and the substrate stage 150.

The film thickness distribution measuring mechanism 200 is constituted by arranging an X-ray source 220 and a detector 230 in a chamber 210, as shown in FIG. 8. X rays from the X-ray source 220 is applied onto the substrate 140, and fluorescent X rays generated on the substrate 140 are detected by the detector 230. Furthermore, the film thickness distribution in the in-plane direction of the substrate 140 is measured by executing the detection while moving the stage 150 in an XY direction.

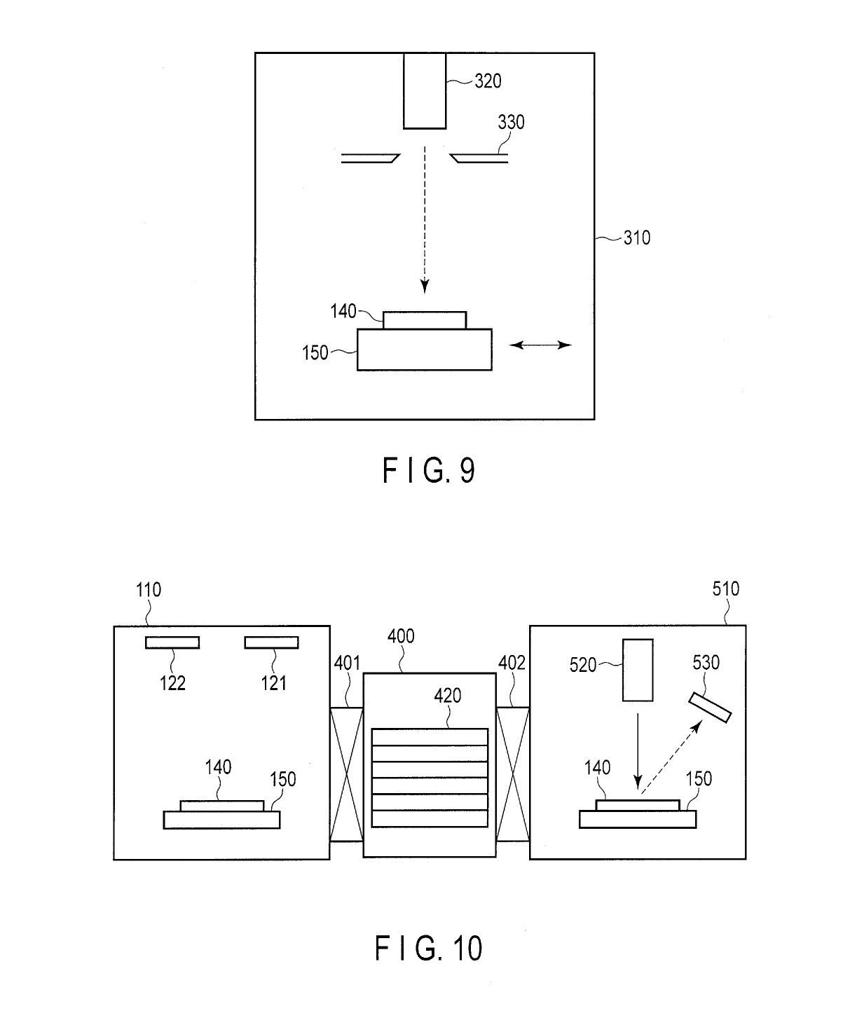

The ion irradiation mechanism 300 comprises an ion source 320, an accelerating electrode 330, etc. inside a chamber 310 as shown in FIG. 9, such that the surface of the substrate 140 can be irradiated with ions emitted from the ion source 320. If the stage 150 is designed to be movable in the XY direction, a desired portion of the substrate 140 can be selectively irradiated with the ions.

Next, an example of manufacturing a magnetoresistive element using the manufacturing apparatus of the present embodiment will be described.

First, one of a plurality of substrates 140 contained in a magazine of the transfer chamber 400 is conveyed into the chamber 110 for sputtering. In the chamber 110, a CoFeB film is formed on the substrate 140 by sputtering the CoFeB target 122 using RF, in the Ar gas atmosphere. As regards the conveyance of the substrate 140, the substrate 140 alone may be conveyed or the substrate stage 150 on which the substrate 140 is placed may be conveyed.

Subsequently, in the chamber 110, an MgO film is formed on the substrate 140 by sputtering the MgO target 121 using RF, in the Ar gas atmosphere. In other words, the MgO film is formed on the CoFeB film.

Next, the substrate 140 is conveyed into the chamber 210 for measurement of the film thickness via the transfer chamber 400. In the chamber 210, the surface of the substrate 140 is obliquely irradiated with the X rays. By detecting the fluorescent X rays obtained at this time by the detector 230, the film thickness of the MgO film is measured. Furthermore, film thickness distribution of the MgO film is measured by executing the above-described measurement while moving the stage 150 in the XY direction.

Next, the substrate 140 is conveyed into the chamber 310 for ion irradiation via the transfer chamber 400. In the chamber 310, the surface of the substrate 140 is selectively irradiated with the ions, based on the measured film thickness distribution. In other words, a portion of the MgO film having a greater thickness is irradiated with the ions. A defect can be generated at a portion having a greater thickness by the ion irradiation, and the resistance can be thereby reduced at the portion having the greater thickness.

Next, the substrate 140 is conveyed into the chamber 110 for sputtering via the transfer chamber 400. In the chamber 110, a CoFeB film is formed on the substrate 140 by sputtering the CoFeB target 122 using RF, in the Ar gas atmosphere. Thus, the CoFeB film which is an upper magnetic layer is formed and the MTJ element is completed.

Thus, according to the present embodiment, the difference in resistance based on the difference in the film thickness of the MgO film can be corrected by forming the MgO film by the sputtering mechanism 100, measuring the film thickness of the MgO film by the film thickness distribution measuring mechanism 200, and irradiating the MgO film with the ions by the ion irradiation mechanism 300 in accordance with the measured film thickness. For this reason, the resistance distribution uniform in the radial direction can be obtained, and the same advantage as that of the first embodiment can be obtained.

In addition, since the sputtering mechanism 100, the film thickness distribution measuring mechanism 200, and the ion irradiation mechanism 300 are connected via the transfer chamber 400, the process from the formation of the MgO film using sputtering to the film thickness measurement and ion irradiation for uniforming the resistance distribution can be successively carried out without exposure to air.

The mechanisms are formed in separate chambers, respectively, in FIG. 6, but may be provided in a single chamber. In addition, not all the mechanisms, but some of the mechanisms may be provided in a single chamber.

For example, if the X rays are applied instead of ions as the beam irradiation mechanism, the film thickness distribution measuring mechanism and the beam irradiation mechanism can be provided in a single chamber. In this case, the chamber 110 for sputtering and a chamber 510 for the measurement of thin film distribution and the beam irradiation may be connected with each other through the transfer chamber 400 as shown in FIG. 10. In the chamber 510, an X-ray source 520 for X-ray irradiation and a detector 530 for detection of the fluorescent X rays are provided. The X-ray source 520 generates X rays of low intensity that may prevent a defect from occurring at the irradiating area at the time of measuring the film thickness distribution, and generates X rays of high intensity that may allow a defect to occur at the irradiating area at the time of correcting the resistance.

In the transfer chamber 400, a magazine 420 for containing a plurality of substrates 140 or substrate stages 150 is contained. The substrates 140 or the substrate stages 150 on which the substrates 140 are placed can be conveyed between the chambers 110 and 510 while maintaining the chambers 110 and 510 in an airtight condition.

When this apparatus is utilized, the CoFeB film and the MgO film is formed on each substrate 140 inside the sputtering mechanism 100 and the substrate 140 is conveyed into the chamber 510 through the transfer chamber 400. Then, the thickness of the MgO film is measured by XRF. After the film thickness is measured, the X rays are applied in accordance with the measured film thickness in the chamber 510. The resistance distribution uniform in the radial direction can be thereby obtained.

The intensity of the X rays for measurement needs to be low enough to prevent a defect from occurring at the MgO film, and the intensity of the X rays for generation of a defect needs to be high.

More specifically, in the measurement of the film thickness, energy of the applied X rays needs to be greater than energy (1.3 keV, 0.5 keV) of characteristic X rays of Mg and O forming a tunnel barrier. To suppress damage caused by excessive energy, however, the energy should be equal to or lower than 10 keV, more preferably, equal to or lower than 5 keV. On the other hand, in the correction of the film thickness, the energy should be equal to or greater than 5 keV, more preferably, equal to or greater than 10 keV, to supply a sufficient excessive energy to the tunnel barrier, change its structure and lower the resistance.

### Third Embodiment

Next, an example of applying the present embodiment to an MRAM will be described.

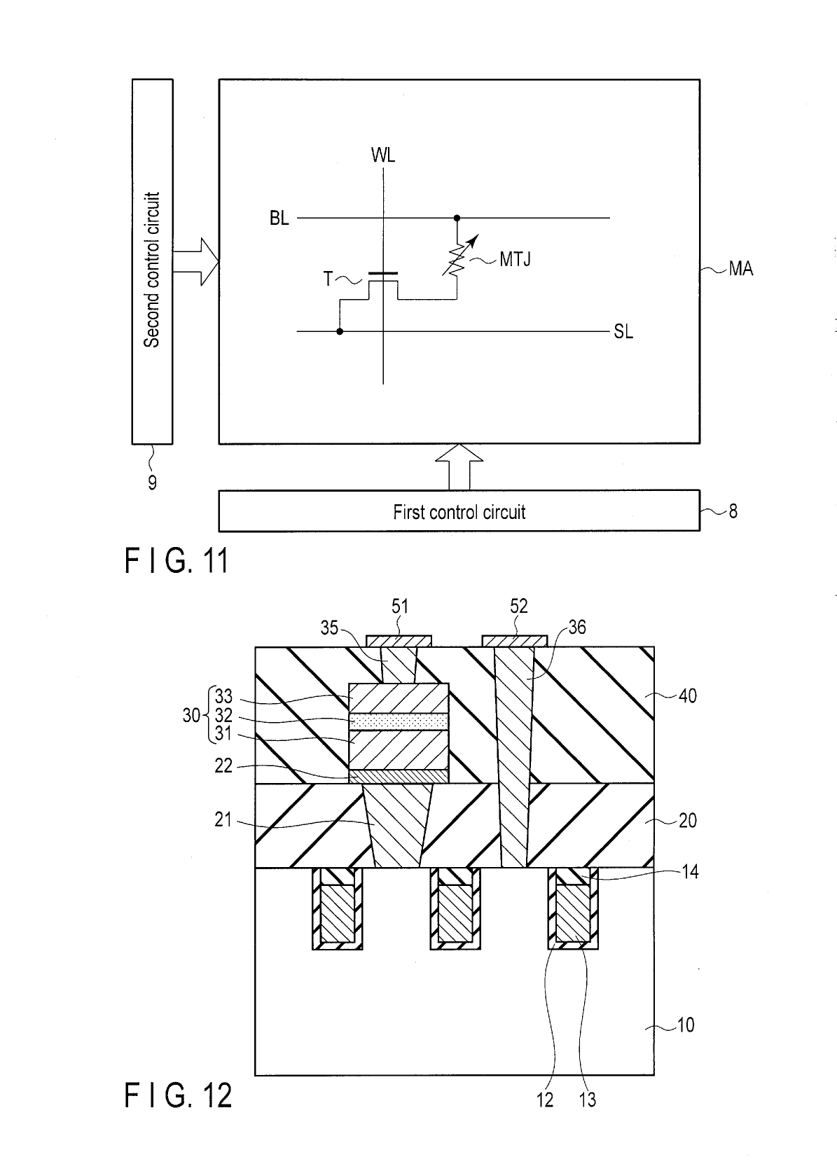

FIG. 11 is a circuit configuration diagram showing a memory cell array of an MRAM using the magnetoresistive element of the present embodiment.

A memory cell in a memory cell array MA comprises a serial connector of an MTJ element serving as a magnetoresistive element and a select transistor (for example, field effect transistor (FET)) T for switching. One of ends of the serial connector (i.e., an end of the MTJ element) is electrically connected to a bit line BL and the other end of the serial connector (i.e., an end of the transistor T) is electrically connected to a source line SL.

A control terminal of the transistor T, for example, a gate electrode of the FET is electrically connected to a word line WL. An electric potential of the word line WL is controlled by a first control circuit 8. In addition, electric potentials of the bit line BL and the source line SL are controlled by a second control circuit 9.

FIG. 12 is a cross-sectional view showing a configuration of a memory cell module using the magnetoresistive element of the present embodiment.

A MOS transistor for switching is formed on a surface portion of an Si substrate 10, and an interlayer insulating film 20 is formed on the MOS transistor. The transistor has a buried gate structure in which a gate electrode 13 is buried in a groove formed in the substrate 10 via a gate insulating film 12. The gate electrode 13 is buried in the middle of the groove and a protective insulating film 14 is formed on the gate electrode 13. In addition, source/drain regions (not shown) are formed by diffusing a p-type or n-type impurity in the substrate 10, on both sides of the buried gate structure.

The configuration of the transistor module is not limited to that having the buried gate structure. For example, the gate electrode may be formed on the surface of the Si substrate 10 via a gate insulating film. The configuration of the transistor module may function as a switching element.

A contact hole for connection with a drain of the transistor is formed in the interlayer insulating film 20, and a bottom electrode (SEC) 21 is buried in the contact hole. The bottom electrode 21 is formed of a crystalline metal, for example, Ta. The material of the bottom electrode is not limited to Ta, but may be any metal capable of being preferably buried in the contact hole and having sufficient conductivity, such as W, TiN and Cu, besides Ta.

A buffer layer 22 formed of, for example, Hf is formed on the bottom electrode 21. The material of the buffer layer is not limited to Hf, but Nb, Mo, Zr, Al, Ti, etc. can be used as the material. To suppress diffusion of the MTJ element to an upper layer side, these nitride films may be used.

A CoFeB film 31 which is a ferromagnetic magnetization free layer, an MgO film 32 which is a tunnel barrier layer, and a CoFeB film 33 which is a ferromagnetic magnetization fixed layer, are deposited on the buffer layer 22. In other words, an MTJ element 30 is formed by sandwiching the tunnel barrier layer between two ferromagnetic layers.

An interlayer insulating film 40 is formed over the substrate on which the MTJ element 30 is formed. A contact plug (TEC) 35 connected with the reference layer (CoFeB film) 33 of the MTJ element 30 is buried in the interlayer insulating film 40. In addition, a contact plug 36 connected with a source of the transistor portion is buried into the interlayer insulating films 40 and 20. An interconnect (BL) 51 connected to the contact plug 35 and an interconnect (SL) 52 connected to the contact plug 36 are formed on the interlayer insulating films 40.

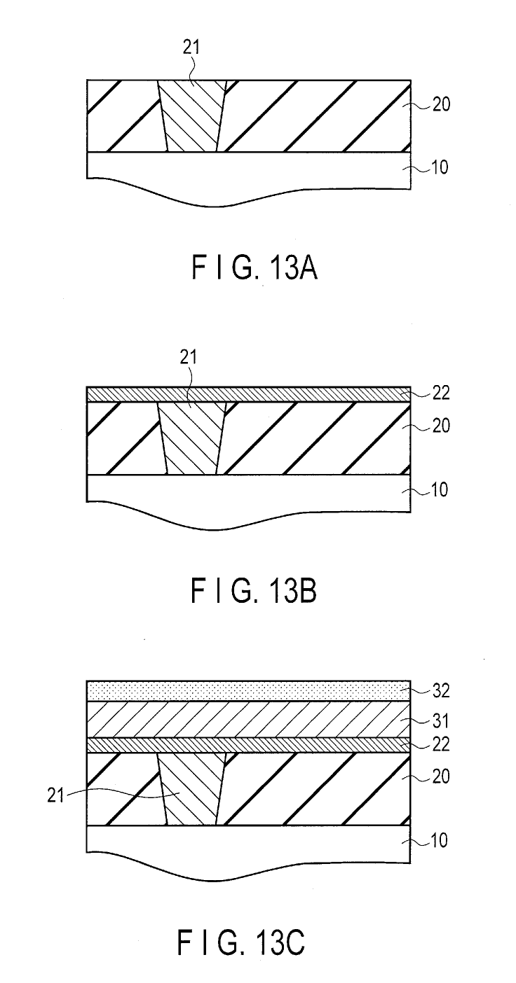

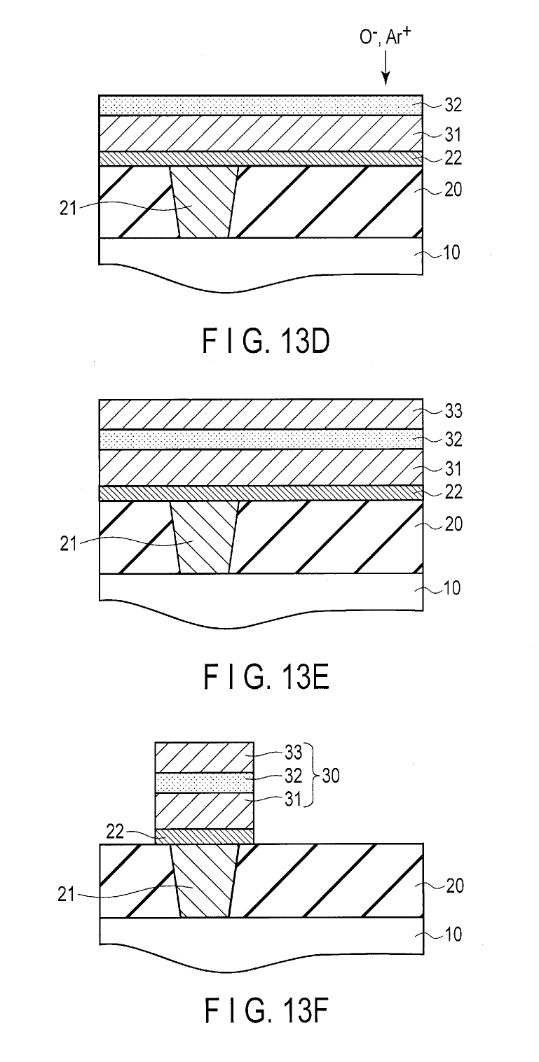

Next, a method of manufacturing a memory cell module of the present embodiment will be described with reference to FIGS. 13A to 13F.

First, a MOS transistor (not shown) for switching having a buried gate structure is formed on a surface portion of the Si substrate 10, and the interlayer insulating film 20 of SiO2, etc. is deposited on the Si substrate 10 by CVD, as shown in FIG. 13A. Then, a contact hole for connection with a drain of the transistor is formed in the interlayer insulating film 20, and the bottom electrode 21 of crystalline Ta is buried in the contact hole. More specifically, a Ta film is deposited on the interlayer insulating film 20 by sputtering, etc. to bury the contact hole, and the Ta film is left in the contact hole alone by removing the Ta film on the interlayer insulating film by chemical mechanical etching (CMP).

Next, the buffer layer 22 formed of, for example, Hf is formed on the interlayer insulating film 20 and the bottom electrode 21, as shown in FIG. 13B.

The CoFeB film 31 which is to be a recording layer of the MTJ element and the MgO film 32 which is to be the tunnel barrier layer are formed on the buffer layer 22, as shown in FIG. 13C, by the sputtering mechanism 100 shown in FIG. 7.

The thickness of the MgO film 32 is measured by the film thickness distribution measuring mechanism 200 shown in FIG. 8. The surface of the MgO film 32 is irradiated with the ions, based on the measured film thickness distribution, as shown in FIG. 13D, by the ion irradiating device 300 shown in FIG. 9. In other words, the portion having a greater film thickness is irradiated with the ions.

The CoFeB film 33 which is to be a reference layer of the MTJ element is formed by the sputtering using the sputtering mechanism 100 shown in FIG. 7, as shown in FIG. 13E. A multilayered structure for formation of the MTJ element having the nonmagnetic tunnel barrier layer sandwiched between the ferromagnetic layers is thereby formed.

The MTJ element 30 is formed by processing the layer portions 22, 23, 31, 32 and 33 in a cell pattern, as shown in FIG. 13F. More specifically, a mask in a cell pattern is formed on the CoFeB film 33, and the film is subjected to selective etching by RIE, etc. such that the layer portions are left in an insular shape on the bottom electrode 21.

After this, the structure shown in FIG. 12 can be obtained by forming the interlayer insulating film 40, forming the contact plus 35 and 36, and forming the interconnects 51 and 52.

Thus, according to the present embodiment, the memory cell module of the MRAM can be formed by forming the MTJ element on the substrate having the select transistor. Then, the resistance distribution of the MgO film 32 can be uniformed by forming the MgO film 32 which is the tunnel barrier by sputtering and selectively irradiating the MgO film 32 with the ions in accordance with the film thickness of the MgO film 32, at the formation of the MTJ element 30. For this reason, enhancement of the properties of the MTJ element 30 can be attempted.

### Modified Embodiment

The invention is not limited to the above-described embodiments.

The insulating film having the film thickness uniformed is not limited to the MgO film. The insulating film may be a nonmagnetic insulating film which functions as the tunnel barrier, and a film of, for example, AlN, AlON, Al₂O₃, etc. can be used as the insulating film. Furthermore, the insulating film can be applied not only to the tunnel barrier of the MTJ element, but also to various insulating films.

The manufacturing device may be any device comprising the sputtering mechanism, the film thickness distribution measuring mechanism and the beam irradiation mechanism, and the mechanisms may be formed in a single chamber or may be formed in independent chambers.

The film thickness distribution measuring mechanism can use not only the XRF, but also an ellipsometer utilizing the laser beam irradiation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing an insulating film, comprising:
forming an insulating film on a substrate by sputtering;
measuring a thickness of the insulating film at a plurality of locations; and
irradiating a surface portion of the insulating film with X rays or ions, based on the thickness.

2. The method of claim 1, wherein
X-ray Fluorescence Analysis of detecting fluorescent X rays generated from the insulating film by the X ray irradiation is employed as measuring the thickness of the insulating film.

3. The method of claim 1, wherein
the insulating film is a nonmagnetic layer of an MTJ element formed by sandwiching the nonmagnetic layer between magnetic layers.

4. The method of claim 3, wherein
the nonmagnetic layer is MgO.

5. The method of claim 3, wherein
the irradiating with the X rays or the ions, selectively, is to irradiate a portion of a greater film thickness so as to uniform in a plane a resistance distribution of the nonmagnetic layer.

6. The method of claim 1, wherein
the forming the insulating film and the irradiating with the X rays or the ions are executed in different chambers.

7. A method of manufacturing a magnetoresistive element, comprising:
forming a first magnetic layer on a substrate by sputtering;
forming a nonmagnetic layer on the first magnetic layer by sputtering;
measuring a thickness of the nonmagnetic layer at a plurality of locations;
irradiating a part of the nonmagnetic layer with X rays or ions, based on the thickness; and
forming a second magnetic layer on the nonmagnetic layer irradiated with the X rays or the ions.

8. The method of claim 7, wherein
X-ray Fluorescence Analysis of detecting fluorescent X rays generated from the nonmagnetic layer by the X ray irradiation is employed as measuring the thickness of the nonmagnetic layer.

9. The method of claim 7, wherein
MgO is used as the nonmagnetic layer.

10. The method of claim 7, wherein
the forming the first magnetic layer, the forming the second magnetic layer, and the forming the nonmagnetic layer are executed in a same chamber, and the irradiating with the X rays or the ions is executed in a chamber different from the chamber.

11. The method of claim 7, wherein
the substrate comprises a semiconductor substrate, an interlayer insulating film formed on the semiconductor substrate, and a bottom electrode buried in the interlayer insulating film, and
the forming the first magnetic layer is to form the first magnetic layer on the bottom electrode via a buffer layer.

12. The method of claim 11, further comprising:
a select transistor for switching on a surface portion of the semiconductor substrate,
wherein the bottom electrode is connected to one of a source and a drain of the select transistor.

13. An insulating film manufacturing apparatus, comprising:
a sputtering mechanism to form an insulating film on a substrate;
a measuring mechanism to measure a thickness of the insulating film formed on the substrate at a plurality of locations; and
an irradiation mechanism to irradiate a surface portion of the insulating film with X rays or ions, based on the thickness.

14. The apparatus of claim 13, wherein
the measuring mechanism employs X-ray Fluorescence Analysis of detecting fluorescent X rays generated from the insulating film by the X ray irradiation.

15. The apparatus of claim 14, wherein
an X-ray irradiation energy of the measuring mechanism is smaller than an X-ray irradiation energy of the irradiating mechanism.

16. The apparatus of claim 13, wherein
the measuring mechanism and the irradiation mechanism are provided in a chamber, the measuring mechanism and the irradiation mechanism, and the sputtering mechanism are provided in different chambers, and the chambers are connected with each other via a transfer chamber.

17. The apparatus of claim 13, wherein
the insulating film is a nonmagnetic layer of an MTJ element formed by sandwiching the nonmagnetic layer between magnetic layers.

18. The apparatus of claim 17, wherein
the nonmagnetic layer is MgO.

19. The apparatus of claim 17, wherein
the irradiation mechanism lowers a resistance of an irradiating area irradiation with the X rays or the ions, and an irradiation amount is controlled to uniform in a plane a resistance distribution in the nonmagnetic layer.
